(19) United States
(12) Patent Application Publication
(10) Pub. No.: US 2006/0184850 A1
(43) Pub. Date: Aug. 17, 2006

(54) Apparatus for preventing bus reset when removing a device from an IEEE 1394 network

(75) Inventors: Ho-Chul Shin, Seongnam-si (KR); Young-Seop Han, Suwon-si (KR); Yun-Je Oh, Yongin-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/354,717

(22) Filed: Feb. 15, 2006

(30) Foreign Application Priority Data
Feb. 15, 2005 (KR) 12509/2005

(51) Int. Cl. G01R 31/28; G06F 3/00; G06F 11/00; G06F 13/42

(52) U.S. Cl. 714/741; 710/17; 710/105; 714/56

(57) ABSTRACT

Disclosed is an apparatus for preventing bus reset when a node is removed in an Institute of Electrical and Electronics Engineers (IEEE) 1394 network. The apparatus includes a tone signal generator for generating a tone signal substantially identical to a tone signal generated by a second node and transferring the generated tone signal to a first node and a switch for blocking the tone signal generated by the tone signal generator when the second node is connected to the network, and transferring the tone signal generated by the tone signal generator to the first node when removal of the second node is detected.

### CLAIM OF PRIORITY

This application claims the benefit of the earlier filing date of that patent application entitled “Apparatus For Preventing Bus Reset From Occurring When Device Is Removed In IEEE 1394 Network,” filed in the Korean Intellectual Property Office on Feb. 15, 2005 and assigned Serial No. 2005-12509, the contents of which are hereby incorporated by reference.

### BACKGROUND OF THE INVENTION

1. Field of the Invention

The present invention relates generally to an Institute of Electrical and Electronics Engineers (IEEE) 1394 network standard, and more specifically to an apparatus for preventing a bus reset signal from being generated when a system is detached from an IEEE 1394 network.

2. Description of the Related Art

The existing expansion bus or interface has not kept pace with the development speed of other technologies, and hampers the development of other technologies in the present high performance multimedia age. A bottleneck between a peripheral device and a body has been a great obstacle in improving the overall speed of a computer system. A new interface developed in order to solve these problems is an IEEE 1394 protocol. A conventional IEEE 1394 technology corresponds to a serial bus interface standard jointly proposed by Apple Inc and Texas Instrument Inc, which has been developed with the codename “FireWire”. The IEEE 1394 technology was agreed and standardized by USA IEEE on December 1995.

Generally, an IEEE 1394 protocol may be referred to as a standard bus interface for a network Personal Computer (PC) and a portable computer.

An IEEE 1394, may connect a maximum of 63 nodes as a serial bus interface, that gives priority to isochronous data in processing the isochronous data (e.g. AV stream data, etc.) and asynchronous data (e.g. control data, packet data, etc.), so that it can insure a Quality of Service (QoS) for AV data, etc., used for a home network.

An IEEE 1394a interface defines bit rates of S100, S200 and S400, and an IEEE 1394b interface defines an optical medium such as a POF, a GOF and an MMF in cable environments, so that it is possible to insure a high speed of 3.2 Gbps.

In the IEEE 1394 protocol, bus management and a transaction layer, which belongs to the well-known OSI software stack, take charge of configuration among IEEE 1394 nodes and a root node for bus management has not yet been specified, when a new IEEE 1394 device is removed or added, a bus reset of an entire IEEE 1394 system is carried out and a new node configuration is determined.

An IEEE 1394 cable, which is a medium for a connection of such an IEEE 1394 network, may be classified as a 6 pin cable and a 4 pin cable. FIG. 1 is a diagram illustrating a conventional 6 pin cable.

Hereinafter, an IEEE 1394 cable will be described with reference to FIG. 1. The IEEE 1394 cable includes two power lines (VCC and GND) 11 and four data lines TPA+/−12 and TPB+/−13. In a 4 pin cable, the two power lines 11 are omitted.

Such an IEEE 1394 network reconfigures a system by performing a bus reset in order to support a hot plugging. The bus reset occurs when an IEEE 1394 device is plugged in to the IEEE 1394 network or is pulled off (removed) the IEEE 1394 network. If the bus reset occurs, the IEEE 1394 network deletes the existing configuration, initializes the entire bus of the system, and then performs a tree identification process and a self identification process, thereby re-configuring or re-establishing the entire bus of the system. Accordingly, a user does not need to separately perform a setup for the system's configuration.

However, in the reconfiguration process of the IEEE 1394 network as described above, the bus reset is inevitably required. When the bus reset occurs during data transmission, data may be lost.

FIGS. 2A and 2B illustrate a case in which bus reset occurs during transmission of important materials in an existing IEEE 1394 network.

Referring to FIG. 2A, an IEEE 1394 network including a plurality of nodes 21 to 26 is shown and important data 201 are transmitted between a node 23 and a node 26.

FIG. 2B illustrates a case wherein the node 21 is removed from the network and, a bus reset occurs in the illustrated IEEE 1394 network. Therefore, the transmission of the important data 201 is stopped. Hence, the transmission of the important data 201 is affected by the removal of the node 21 which has no actual connection with the transmission of the data 201. Accordingly, this problem of resetting the bus represents an issue when a high QoS is required. The bus reset may occur when an IEEE 1394 device is plugged in to the IEEE 1394 network or is removed from the IEEE 1394 network. When an IEEE 1394 device is plugged into the bus, the bus reset is required because configuration of the network is required in order to use the plugged device. However, when an IEEE 1394 device is simply removed from the IEEE 1394 network, reconfiguration of a bus is not substantially useful. That is, because a maximum of 255 node IDs may be assigned to the device, the reconfiguration of the bus through the bus reset is not necessary for removing the node IDs, so long as IDs of nodes connected in a daisy chain are not altered.

### SUMMARY OF THE INVENTION

Accordingly, the present invention has been made to solve the above-mentioned problems occurring in the prior art and provides additional advantages, by providing an apparatus for preventing bus reset from occurring in an IEEE 1394 network by causing the IEEE 1394 network not to detect removal of an IEEE 1394 device when the IEEE 1394 device is removed from the IEEE 1394 network.

According to one aspect of the present invention, there is provided an apparatus for preventing bus reset when a node is removed in an Institute of Electrical and Electronics Engineers (IEEE) 1394 network. The apparatus includes a tone signal generator for generating a tone signal identical to a tone signal generated by a second node and transferring the generated tone signal to a first node and a switch for blocking the tone signal generated by the tone signal generator when the second node is connected to the network, and transferring the tone signal generated by the tone signal generator to the first node when removal of the second node is detected.

According to the present invention, the tone signal generator includes a first IEEE 1394 connector for a connection of the first node, a second IEEE 1394 connector for a connection of the second node, a first Phase Lock Loop (PLL) for extracting a reference frequency from a downlink connection between the first IEEE 1394 connector and the second IEEE 1394 connector, a second PLL for extracting a target frequency from an uplink connection between the first IEEE 1394 connector and the second IEEE 1394 connector, a comparator for receiving output of the first PLL and the second PLL and computing a phase difference, a pulse generator for receiving output of the comparator and the outputs of the first and the second PLLs, and generating the tone signal generated by the second node, and an oscillator for providing a pulse to the pulse generator.

### BRIEF DESCRIPTION OF THE DRAWINGS

The above features and advantages of the present invention will be more apparent from the following detailed description taken in conjunction with the accompanying drawings, in which:

FIG. 1 illustrates a 6 pin cable used for a connection between IEEE 1394 devices;

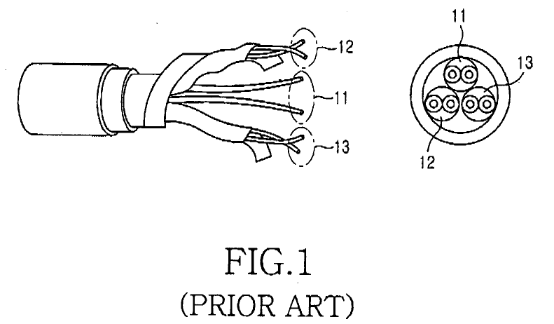

FIGS. 2A and 2B illustrate a case in which bus reset occurs during transmission of important materials in an existing IEEE 1394 network;

FIG. 3 illustrates a block diagram of an apparatus for preventing bus reset from occurring in an IEEE 1394 network according to one embodiment of the present invention;

FIG. 4 illustrates a tone signal used for checking a connection between nodes, in an IEEE 1394 network, according to one embodiment of the present invention; and

FIG. 5 illustrates a tone signal used for checking a connection between nodes, in an IEEE 1394 network, and speed codes according to one embodiment of the present invention.

### DETAILED DESCRIPTION

An embodiment of the present invention will be described in detail herein below with reference to the accompanying drawings. The same reference numerals are used to designate the same elements as those shown in other drawings. For the purposes of clarity and simplicity, a detailed description of known functions and configurations incorporated herein will be omitted as it may obscure the subject matter of the present invention.

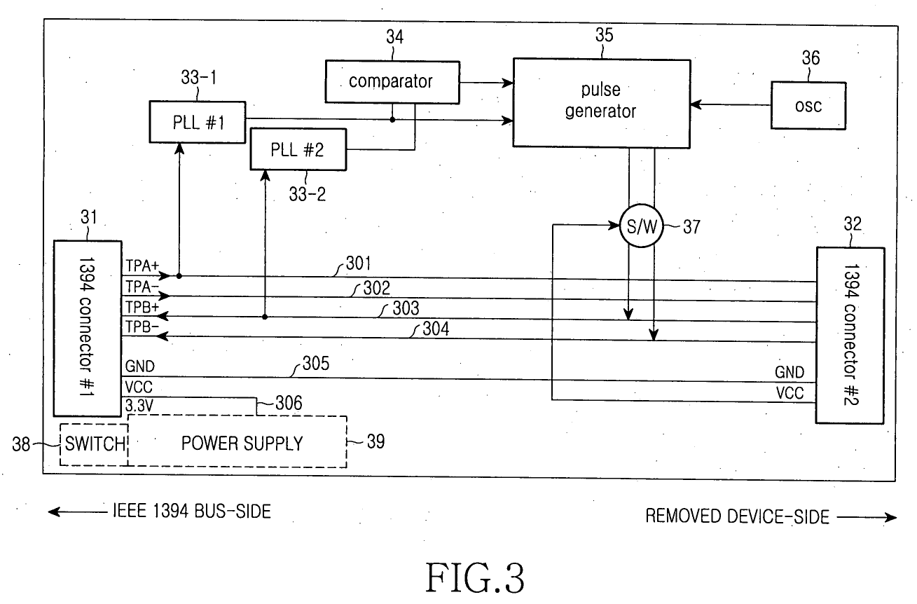

FIG. 3 is a block diagram illustrating the construction of an apparatus for preventing a bus reset from occurring in an IEEE 1394 network when an IEEE 1394 device is removed from the IEEE 1394 network according to one embodiment of the present invention.

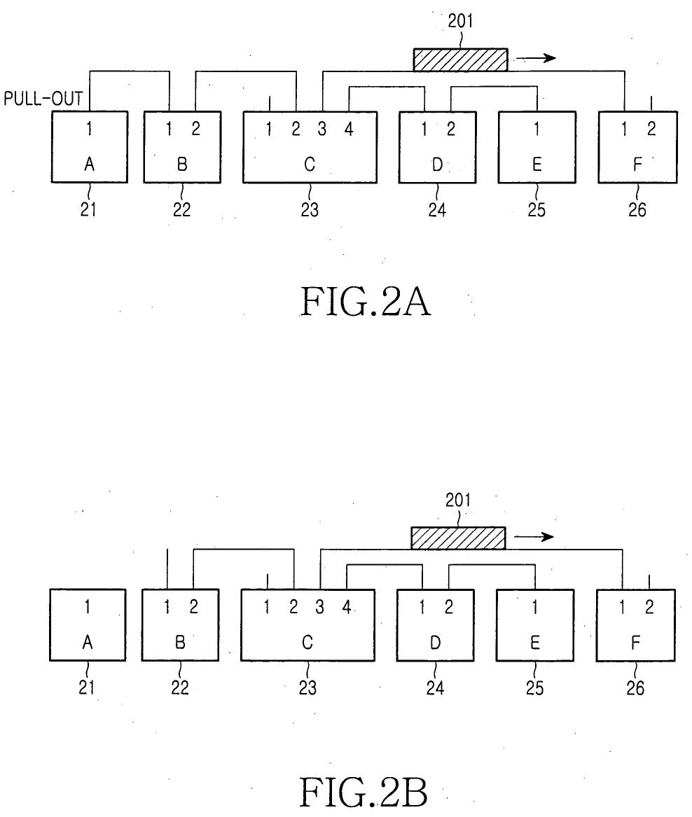

The apparatus will be described through a connection between two IEEE 1394 devices 21 and 22 in FIG. 2. First, connection configuration between the IEEE 1394 devices will be described through a connection of an IEEE 1394 cable between the node 21, which is to be removed, and the node 22 which is a device in the IEEE 1394 network. Generally, whether a correspondent node proposed by an IEEE 1394 standard is connected and operates or is removed the connection or removal is checked through a tone signal.

FIG. 3 is a block diagram illustrating an apparatus for preventing bus reset from occurring in an IEEE 1394 network according to one embodiment of the present invention.

Referring to FIG. 3, the apparatus includes a first IEEE 1394 connector 31, e.g., a 6-pin connector, a second IEEE 1394 connector 32, connections TPA+/−301 and 302, respectively, and TPB+/−303 and 304, respectively, between the first IEEE 1394 connector 31 and the second IEEE 1394 connector 32. Also shown are two Phase Lock Loops (PLLs) 33-1 and 33-2 respectively connected to TPA+301 and TPB+303, a comparator 34, a pulse generator 35, an oscillator 36, for providing a pulse to the pulse generator 35, and a switch 37. The comparator 34 receives output from the PLLs 33-1 and 33-2 and computes a phase difference “delta T”. The pulse generator 35 receives output from the comparator 34 and output from the PLLs 33-1 and 33-2, generates a tone signal, and transfers the tone signal to TPB+/−(303, 304). The switch 37 detects removal of a node from the second IEEE 1394 connector 32, and transfers the tone signal according to a tone frequency in an existing node connection, which has been generated through the pulse generator 35, to the first IEEE 1394 connector 31.

The apparatus further includes a second switch 38 which is connected to the first IEEE 1394 connector 31, which controls the on/off state of a power supply 39 supplying VCC power.

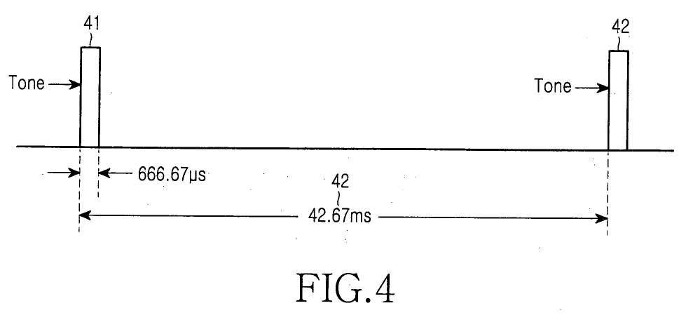

FIG. 4 is a diagram illustrating a tone signal used for checking a connection between nodes, proposed by an IEEE 1394 standard, according to one embodiment of the present invention.

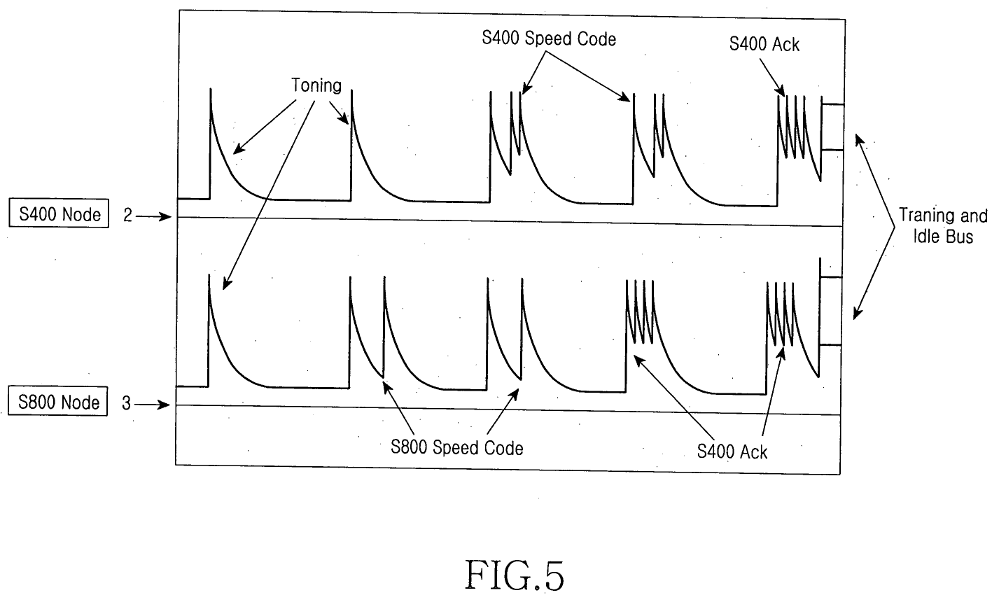

As illustrated in FIG. 4, the tone signal is a pulse with a width of 666.67 μs, which has a period 42 of 42.67 ms. The tone signal is periodically sent through a transmit (Tx) (in the case of an IEEE 1394a, a TPA) of an IEEE 1394 transmission cable. If the tone signal has arrived at the physical (PHY) layer of a correspondent node for the first time, the PHY layer checks that a different node has been connected to the correspondent node, sends a speed code, and receives an ACK signal. FIG. 5 illustrates both a tone signal used for checking a connection between nodes, proposed by an IEEE 1394 standard, and speed codes according to one embodiment of the present invention.

The speed codes as illustrated in FIG. 5 are slightly different in an S400 (maximum 400 M) node and an S800 (in the case of an IEEE 1394b) node.

A node checks connection or disconnection with a correspondent node through an existence of the tone signal periodically received as illustrated in FIGS. 4 and 5. Accordingly, in one embodiment of the present invention, even though one node is removed from a bus due to power down, cable removal, etc., a tone signal with the same frequency is transferred to a correspondent node, so that the correspondent node detects a connection with the removed node and bus reset does not occur.

Hereinafter, an operation of the apparatus for preventing bus reset from occurring when an IEEE 1394 device is removed according to the present invention will be described with reference to FIGS. 3 to 5. First, the TPA lines 301 and 302 from the node 22 periodically generate tone signals. This is because a correspondent node has not yet been connected and a PHY layer does not send valid data. The reference frequency fr(t) of the tone signals is extracted through the PLL 33-1 and is input to the comparator 34 and the pulse generator 35.

When the node 21 is connected for the first time, the TPB lines 303 and 304 generate tone signals before a connection with the correspondent node 22. Accordingly, a target frequency ft(t) is extracted through the PLL 33-2 by means of these tone signals, and is input to the comparator 34 and the pulse generator 35.

The comparator 34 extracts an interval “delta T, d(t)” between the reference frequency fr(t) and the target frequency ft(t), and transfers the interval delta T to the pulse generator 35.

The pulse generator 35 is set to operate at 42.67 ms, which is a period of a tone signal, and 666.67 μs, which is a width of a tone signal, and generates a tone signal with an interval of d(t) by means of the reference frequency fr(t).

In a typical case, the generated tone signal is blocked by the switch 37. If the node 21 is removed, VCC from the node 21 falls to 0V, and this causes triggering. Therefore, a generated tone signal is input in to the network.

Accordingly, when the node 21 is removed, the node 22 does not detect the removal of the node 21 as the node 22 receives a generated tone signal with the same period as that of an existing generated tone signal. Accordingly, bus reset does not occur.

When a bus reset occurs due for some reason, the node 22 is then able to detect the removal of the node 21 through a reconfiguration operation of a network, as described previously.

According to the present invention as described above, bus reset is prevented from occurring due to removal of a device in an IEEE 1394 network, so that QoS can be ensured and a service can be provided in realtime.

Although a preferred embodiment of the present invention has been described for illustrative purposes, those skilled in the art will appreciate that various modifications, additions and substitutions are possible, without departing from the scope and spirit of the invention as disclosed in the accompanying claims, including the full scope of equivalents thereof.

What is claimed is:

1. An apparatus for preventing bus reset from occurring when a second node is removed in an Institute of Electrical and Electronics Engineers (IEEE) 1394 network including the second node connected to a first node, the apparatus comprising:
a tone signal generator for generating a tone signal substantially identical to a tone signal generated by the second node and transferring the generated tone signal to the first node; and
a switch for blocking the tone signal generated by the tone signal generator when the second node is connected to the network, and transferring the tone signal generated by the tone signal generator to the first node when removal of the second node is detected.

2. The apparatus as claimed in claim 1, wherein the tone signal generator comprises:
a first IEEE 1394 connector for a connection of the first node;
a second IEEE 1394 connector for a connection of the second node;
a first Phase Lock Loop (PLL) for extracting a reference frequency from a downlink connection between the first IEEE 1394 connector and the second IEEE 1394 connector;
a second PLL for extracting a target frequency from an uplink connection between the first IEEE 1394 connector and the second IEEE 1394 connector;
a comparator for receiving output of the first PLL and the second PLL and computing a phase difference;
a pulse generator for receiving both output of the comparator and the output of the first PLLs, and generating the tone signal generated by the second node; and
an oscillator for providing a pulse to the pulse generator.

3. The apparatus as claimed in claim 1, wherein the switch detects the removal of the second node through a power signal from the second node.

4. The apparatus as claimed in claim 1, wherein the tone signal is a pulse with a width of 666.67 μs, which has a period of 42.67 ms.

5. A method for preventing bus reset from occurring when a second node is removed in an Institute of Electrical and Electronics Engineers (IEEE) 1394 network including the second node connected to a first node, the method comprising the steps of:
generating a tone signal substantially identical to a tone signal generated by the second node;
blocking the tone signal generated by the tone signal generator when the second node is connected to the network; and
transferring the tone signal generated by the tone signal generator to the first node when removal of the second node is detected.

6. The method as claimed in claim 5, wherein the step of generating a tone signal comprises the steps of:
comparing an output of a reference signal and a target signal, wherein the reference signal is obtained from downlink connection between the first and second nodes and the target signal is obtained from an uplink connection between the first and second nodes;
computing a phase difference between the reference signal and the target signal;
generating a pulse at a frequency substantially equal to a tone generated by the second node; and
generating the tone signal based on the reference signal, the target signal, the pulse and the phase difference.

7. The method as claimed in claim 5, wherein the step of blocking the tone comprises the step of:
monitoring a power status of the second node.

8. The method as claimed in claim 5, wherein the tone signal is a pulse with a width of 666.67 μs, which has a period of 42.67 ms.
